(19) United States
(12) Patent Application Publication
(10) Pub. No.: US 2025/0296116 A1
(43) Pub. Date: Sep. 25, 2025

(54) HAPTIC ACTUATOR MODULE AND ASSEMBLY USING ELECTROSTATIC ATTRACTION AND PIN STIMULATION

(71) Applicant: SEOUL NATIONAL UNIVERSITY R&DB FOUNDATION, Seoul (KR)

(72) Inventors: Yong Hae HEO, Cheonan-si (KR); Yuk Gwon SONG, Cheonan-si (KR); Su Jin PARK, Seoul (KR); Ji Soo HA, Seoul (KR); Sang Youn KIM, Seoul (KR)

(73) Assignee: SEOUL NATIONAL UNIVERSITY R&DB FOUNDATION, Seoul (KR)

(21) Appl. No.: 19/089,300

(22) Filed: Mar. 25, 2025

(30) Foreign Application Priority Data
Mar. 25, 2024 (KR) 10-2024-0040631

(51) Int. Cl. B06B 1/02

(52) U.S. Cl. CPC B06B 1/0292

(57) ABSTRACT

A haptic actuator module using electrostatic attraction and pin stimulation according to the present invention may include a dielectric elastomer, a first electrode disposed to adjoin a lower surface region that is a lower surface of the dielectric elastomer, a second electrode disposed to adjoin a first upper surface region that is a partial region of an upper surface of the dielectric elastomer, and a module housing having therein an accommodation region configured to accommodate the dielectric elastomer, the first electrode, and the second electrode, the module housing being configured such that an outer surface region, which is an outer surface of the dielectric elastomer, adjoins an inner surface of the accommodation region.

### CROSS-REFERENCE TO RELATED APPLICATIONS

This application claims priority to and the benefit of Korean Patent Application No. 10-2024-0040631 filed in the Korean Intellectual Property Office on Mar. 25, 2024, the entire contents of which are incorporated herein by reference.

### TECHNICAL FIELD

The present invention relates to a haptic actuator module and assembly using electrostatic attraction and pin stimulation, and more particularly, to a haptic actuator module and assembly using electrostatic attraction and pin stimulation, in which electrodes are disposed to adjoin a part of an upper surface of a dielectric elastomer and a lower surface of the dielectric elastomer, and a voltage is applied to the electrodes in a state in which an outer surface of the dielectric elastomer is surrounded by a housing, such that only a partial region of the dielectric elastomer disposed between the electrodes is compressed and decreases in thickness, the remaining region of the dielectric elastomer increases in thickness while corresponding to the increase in thickness of the partial region, and a protruding pin disposed above the remaining region is raised, thereby providing pin stimulation.

### BACKGROUND ART

In the related art, in addition to a configuration in which feedback is provided to a user by using a visual or auditory signal, a tactile signal, such as vibration, is provided as feedback when the user touches a device with the finger, thereby enabling the users to more closely interact with environments.

In the related art, a vibration motor is used as a vibration source for providing the tactile feedback, but there is a problem in that the vibration motor has a large volume and is opaque.

In order to solve the above-mentioned problem with the vibration motor, a haptic device having a dielectric elastomer driver as a vibration source has been developed, but there is a problem in that the dielectric elastomer driver does not provides a force sufficient to allow the user to feel tactility because of low stress.

### SUMMARY OF THE INVENTION

The present invention has been made in an effort to solve the above-mentioned problem, and an object of the present invention is to provide a haptic actuator module and assembly using electrostatic attraction and pin stimulation, in which electrodes are disposed to adjoin a part of an upper surface of a dielectric elastomer and a lower surface of the dielectric elastomer, and a voltage is applied to the electrodes in a state in which an outer surface of the dielectric elastomer is surrounded by a housing, such that only a partial region of the dielectric elastomer disposed between the electrodes is compressed and decreases in thickness, the remaining region of the dielectric elastomer increases in thickness while corresponding to the increase in thickness of the partial region, and a protruding pin disposed above the remaining region is raised, thereby providing pin stimulation.

A haptic actuator module using electrostatic attraction and pin stimulation according to the present invention may include a dielectric elastomer, a first electrode disposed to adjoin a lower surface region that is a lower surface of the dielectric elastomer, a second electrode disposed to adjoin a first upper surface region that is a partial region of an upper surface of the dielectric elastomer, and a module housing having therein an accommodation region configured to accommodate the dielectric elastomer, the first electrode, and the second electrode, the module housing being configured such that an outer surface region, which is an outer surface of the dielectric elastomer, adjoins an inner surface of the accommodation region.

The haptic actuator electrostatic attraction and pin stimulation according to the present invention may further include: a third electrode disposed to adjoin a third upper surface region that is a partial region of a second upper surface region that is an upper surface of the dielectric elastomer that does not adjoin the second electrode; and a protruding pin having a predetermined thickness and disposed above the third electrode.

The module housing may have a module cover configured to open or close the accommodation region, and an upper surface of the protruding pin may adjoin a lower surface of the module cover.

The haptic actuator module using electrostatic attraction and pin stimulation according to the present invention may further include: a power source configured to supply a voltage between the first electrode and the second electrode, in which a first elastomer region of the dielectric elastomer, which is disposed below the first upper surface region and between the first electrode and the second electrode, is compressed and decreased in thickness by electrostatic attraction when a voltage is applied between the first electrode and the second

A second elastomer region of the dielectric elastomer, which is disposed below the second upper surface region and is the remaining region other than the first elastomer region, may increase in thickness while corresponding to the decrease in thickness of the first elastomer region when the voltage is applied between the first electrode and the second electrode.

The third electrode and the protruding pin may be raised by the increase in thickness of the second elastomer region when the voltage is applied between the first electrode and the second electrode.

The module cover may protrude upward as the third electrode and the protruding pin are raised by the increase in thickness of the second elastomer region when the voltage is applied between the first electrode and the second electrode.

A haptic actuator assembly using electrostatic attraction and pin stimulation according to the present invention may include: the above-mentioned plurality of haptic actuator modules using electrostatic attraction and pin stimulation; and an assembly controller configured to provide haptics by applying voltages between first and second electrodes of one or more haptic actuator modules using electrostatic attraction and pin stimulation among the plurality of haptic actuator modules using electrostatic attraction and pin stimulation, in which the plurality of haptic actuator modules using electrostatic attraction and pin stimulation are disposed adjacent to one another.

According to one aspect of the present invention, the electrodes may be disposed to adjoin a part of the upper surface of the dielectric elastomer and the lower surface of the dielectric elastomer, and a voltage may be applied to the electrodes in the state in which the outer surface of the dielectric elastomer is surrounded by the housing, such that only a partial region of the dielectric elastomer disposed between the electrodes is compressed and decreases in thickness, the remaining region of the dielectric elastomer increases in thickness while corresponding to the increase in thickness of the partial region, and the protruding pin disposed above the remaining region is raised, thereby providing various types of pin stimulation.

### BRIEF DESCRIPTION OF THE DRAWINGS

FIG. 1 is a perspective view of a haptic actuator module using electrostatic attraction and pin stimulation according to an embodiment of the present invention.

FIG. 2 is an exploded perspective view of the haptic actuator module using electrostatic attraction and pin stimulation according to the embodiment of the present invention.

FIG. 3 is a cross-sectional view illustrating a case in which no voltage is applied to first and second electrodes of the haptic actuator module using electrostatic attraction and pin stimulation according to the embodiment of the present invention.

FIG. 4 is a cross-sectional view illustrating a case in which a voltage is applied to the first and second electrodes of the haptic actuator module using electrostatic attraction and pin stimulation according to the embodiment of the present invention.

FIG. 5 is a view illustrating a state in which an assembly cover of a haptic actuator assembly using electrostatic attraction and pin stimulation according to the embodiment of the present invention is separated.

FIG. 6 is a cross-sectional view illustrating a case in which no voltage is applied to the second electrodes of all the haptic actuator modules included in the haptic actuator assembly using electrostatic attraction and pin stimulation according to the embodiment of the present invention.

FIG. 7 is a cross-sectional view illustrating a first case in which a voltage is applied to the first and second electrodes of any one haptic actuator module of the haptic actuator assembly using electrostatic attraction and pin stimulation according to the embodiment of the present invention.

FIG. 8 is a cross-sectional view illustrating a second case in which a voltage is applied to the first and second electrodes of any one haptic actuator module of the haptic actuator assembly using electrostatic attraction and pin stimulation according to the embodiment of the present invention.

### DETAILED DESCRIPTION

Hereinafter, exemplary embodiments are proposed to help understand the present invention. However, the following embodiments are provided just for more easily understanding the present invention, and the contents of the present invention are not limited by the embodiments.

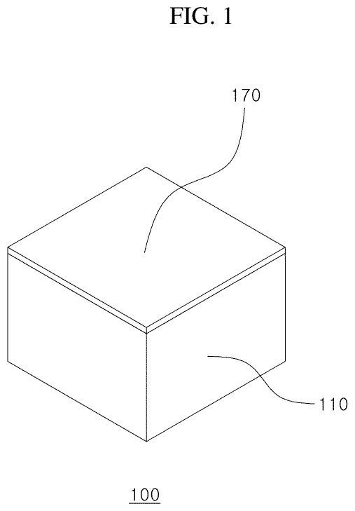

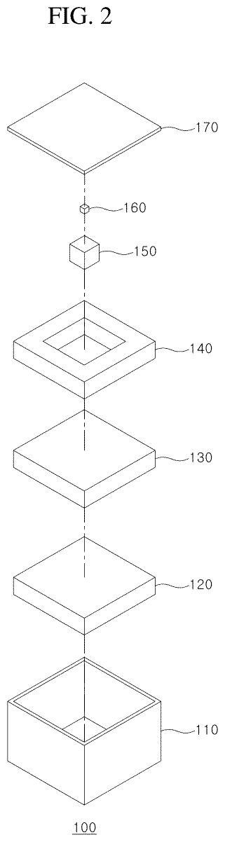

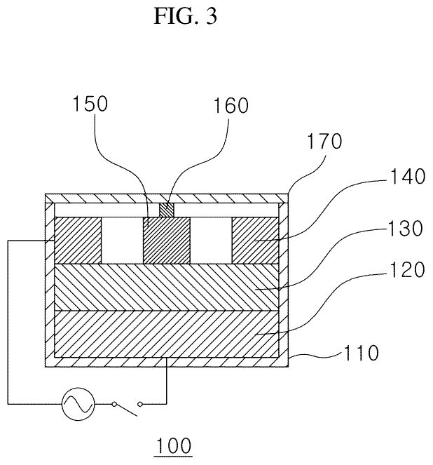

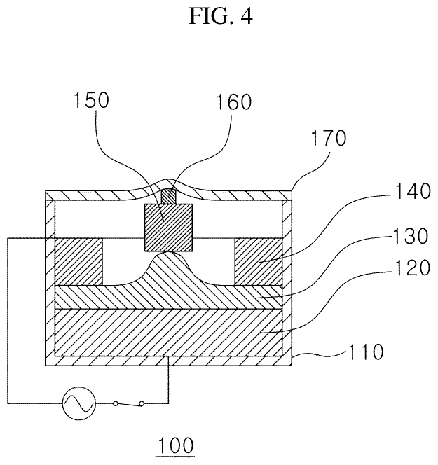

FIG. 1 is a perspective view of a haptic actuator module using electrostatic attraction and pin stimulation according to an embodiment of the present invention, FIG. 2 is an exploded perspective view of the haptic actuator module using electrostatic attraction and pin stimulation according to the embodiment of the present invention, FIG. 3 is a cross-sectional view illustrating a case in which no voltage is applied to first and second electrodes of the haptic actuator module using electrostatic attraction and pin stimulation according to the embodiment of the present invention, and FIG. 4 is a cross-sectional view illustrating a case in which a voltage is applied to the first and second electrodes of the haptic actuator module using electrostatic attraction and pin stimulation according to the embodiment of the present invention.

With reference to FIGS. 1 to 4, a haptic actuator module 100 using electrostatic attraction and pin stimulation according to an embodiment of the present invention (hereinafter, referred to as a ‘haptic actuator module’) may include module housing 110, a first electrode 120, a dielectric elastomer 130, a second electrode 140, a third electrode 150, a protruding pin 160, and a module cover 170.

An accommodation region may be formed inside the module housing 110 and accommodate the first electrode 120, the dielectric elastomer 130, the second electrode 140, the third electrode 150, and the protruding pin 160.

In this case, the accommodation region of the module housing 110 may be formed to surround lower and outer surfaces of the first electrode 120 formed in a quadrangular plate shape, surround an outer surface of the dielectric elastomer 130 formed in a quadrangular plate shape, and surround an outer surface of the second electrode 140 formed in a ‘□’ shape having a hollow inner portion.

The module housing 110 may be formed in a box shape opened at an upper side thereof, and the module cover 170 may be provided to open or close the opened upper side of the module housing 110.

Meanwhile, as described above, the first electrode 120, the dielectric elastomer 130, the second electrode 140, the third electrode 150, and the protruding pin 160 may be stacked and accommodated in the accommodation region of the module housing 110.

Specifically, the dielectric elastomer 130 may be disposed above the first electrode 120 and stacked on the first electrode 120.

In this case, an upper surface of the first electrode 120 may adjoin a lower surface region that is the lower surface of the first electrode 120.

In addition, an area of the upper surface of the first electrode 120 and an area of the lower surface of the first electrode 120 may be equal to each other.

The second electrode 140 and the third electrode 150 may be disposed above the dielectric elastomer 130 and stacked on the dielectric elastomer 130.

In this case, a first upper surface region, which is a partial region of an upper surface of the dielectric elastomer 130, may adjoin a lower surface of the second electrode 140.

In addition, a third upper surface region, which is a partial region of the second upper surface region of the upper surface of the dielectric elastomer 130 and does not adjust the lower surface of the second electrode 140, may adjoin a lower surface of the third electrode 140.

That is, the upper surface of the dielectric elastomer 130 may include the first upper surface region configured to adjoin the lower surface of the second electrode 140, and the second upper surface region configured not to adjoin the lower surface of the second electrode 140, and a part of the second upper surface region may be the third upper surface region configured to adjoin the lower surface of the third electrode 150.

As described above, the second electrode 140 is formed in a ‘□’ shape having a hollow inner portion, and the third electrode 150 may be provided in the hollow inner portion and spaced apart from the second electrode 140.

Meanwhile, the dielectric elastomer 130 may be divided into a first elastomer region and a second elastomer region depending on whether the first electrode 120 and the second electrode 140 are respectively positioned above and below the dielectric elastomer 130.

Specifically, the dielectric elastomer 130 may be divided into the first elastomer region below which the first electrode 120 is disposed and above which the second electrode 140 is disposed, and the second elastomer region below which the first electrode 120 is disposed and above which the second electrode 140 is not disposed.

Meanwhile, the protruding pin 160 may have a predetermined thickness and be disposed above the third electrode 150.

The protruding pin 160 may be disposed at a highest position among the components accommodated in the accommodation region.

In addition, an upper surface of the protruding pin 160 may adjoin an upper surface of the module cover 170.

Meanwhile, the haptic actuator module 100 may further include a power source electrically connected to the first electrode 120 and the second electrode 140 and configured to apply a voltage between the first electrode 120 and the second electrode 140. The power source may include a voltage source, a circuit configured to electrically connect the first electrode 120 and the second electrode 140 to the voltage source, and a switch configured to allow or block electrical conduction to the circuit.

The first electrode 120 may be a positive electrode, and the second electrode 140 may be a negative electrode.

Therefore, the dielectric elastomer 130 may receive an electric field generated by the voltage applied between the lower first electrode 120 and the upper second electrode 140, such that dielectric elastomer 130 may be compressed in a thickness direction and expanded in a planar direction by the electric field.

More specifically, in the dielectric elastomer 130, only the first elastomer region, below which the first electrode 120 is disposed and above which the second electrode 140 is disposed, receives the electric field generated by the voltage applied between the first electrode 120 and the second electrode 140, such that the first elastomer region may be compressed in the thickness direction and expanded in the planar direction.

In this case, an outer side of the first elastomer region of the dielectric elastomer 130 may adjoin an inner surface of the accommodation region, and an inner side of the first elastomer region may adjoin the second elastomer region of the dielectric elastomer 130.

Therefore, the first elastomer region of the dielectric elastomer 130 may be compressed in the thickness direction and expanded in the planar direction. The first elastomer region may be expanded only in a direction toward the second elastomer region without being expanded in a direction toward the inner surface of the accommodation region.

Therefore, the first elastomer region of the dielectric elastomer 130 may decrease in thickness, whereas the second elastomer region of the dielectric elastomer 130 may increase in thickness while corresponding to the decrease in thickness of the first elastomer region because the first elastomer region of the dielectric elastomer 130 is expanded toward the second elastomer region.

Therefore, the third electrode 150, which is disposed in the third upper surface region that is a part of the second upper surface region (an upper portion of the second elastomer region) of the upper surface of the dielectric elastomer 130, and the protruding pin 160, which is disposed above the third electrode 150, may be raised upward as the second elastomer region of the dielectric elastomer 130 increases in thickness.

In this case, as the protruding pin 160, which adjoins the lower and upper surfaces of the module cover 170, is raised upward, a part of the module cover 170 may convexly protrude upward.

To this end, the module cover 170 may be made of a flexible material that allows transformable shapes.

In case that the power source repeatedly applies an alternating current voltage or applies no voltage, the thickness of the second elastomer region repeatedly changes, and the protruding pin 160 repeatedly moves upward or downward, such that a case in which a part of the module cover 170 convexly protrudes upward and a case in which a part of the module cover 170 is kept flat may be repeated.

Therefore, the haptic actuator module 100 may provide the user with pin stimulation that is a sensation in which only a predetermined region vibrates.

Meanwhile, the third electrode 150 may transmit the electric field, which is generated by the voltage applied between the first electrode 120 and the second electrode 140, to an upper region of the module cover 170, the upper region below which the protruding pin 160 is positioned.

Therefore, when the user's body (e.g., a finger) approaches the module cover 170 in the state in which a voltage is applied between the first electrode 120 and the second electrode 140, electrostatic attraction may be applied to the user's body to provide tactility to the user.

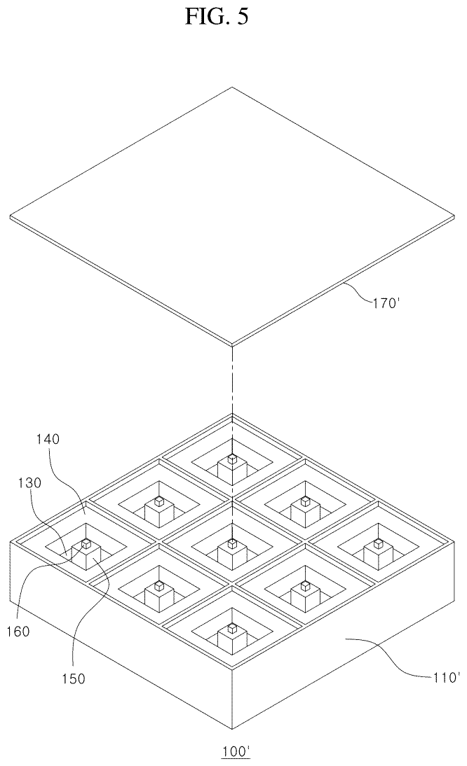

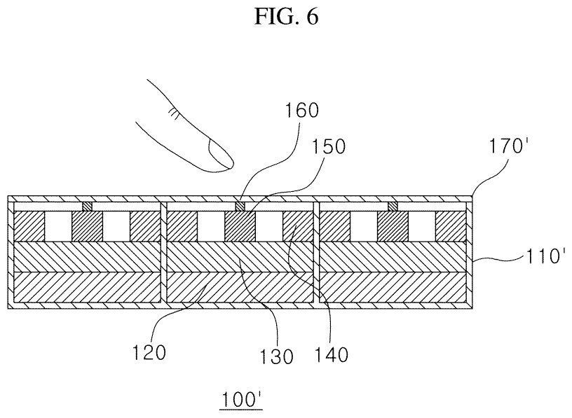

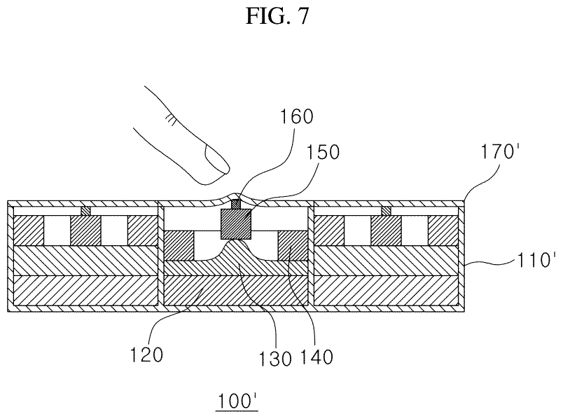

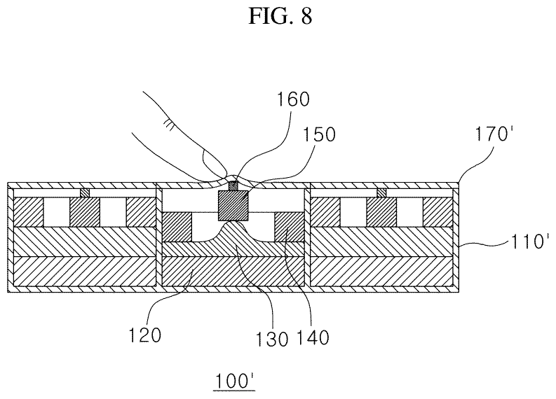

FIG. 5 is a view illustrating a state in which an assembly cover of a haptic actuator assembly using electrostatic attraction and pin stimulation according to the embodiment of the present invention is separated, FIG. 6 is a cross-sectional view illustrating a case in which no voltage is applied to the second electrodes of all the haptic actuator modules included in the haptic actuator assembly using electrostatic attraction and pin stimulation according to the embodiment of the present invention, FIG. 7 is a cross-sectional view illustrating a first case in which a voltage is applied to the first and second electrodes of any one haptic actuator module of the haptic actuator assembly using electrostatic attraction and pin stimulation according to the embodiment of the present invention, and FIG. 8 is a cross-sectional view illustrating a second case in which a voltage is applied to the first and second electrodes of any one haptic actuator module of the haptic actuator assembly using electrostatic attraction and pin stimulation according to the embodiment of the present invention.

With reference to FIGS. 5 to 8, a haptic actuator assembly 100′ using electrostatic attraction and pin stimulation according to the embodiment of the present invention 100′ (hereinafter, referred to as a ‘haptic actuator assembly’) may include the plurality of haptic actuator modules (100 in FIG. 1) and a controller.

In this case, like the above-mentioned haptic actuator module (100 in FIG. 1), the plurality of haptic actuator modules included in the haptic actuator assembly 100′ may each include the module housing 110, the first electrode 120, the dielectric elastomer 130, the second electrode 140, the third electrode 150, the protruding pin 160, the module cover 170, and the power source or include only the first electrode 120, the dielectric elastomer 130, the second electrode 140, the third electrode 150, the protruding pin 160, and the power source, except for the module housing 110 and the module cover 170.

Hereinafter, the haptic actuator assembly 100′ including the plurality of haptic actuator modules each including only the first electrode 120, the dielectric elastomer 130, the second electrode 140, the third electrode 150, the protruding pin 160, and the power source, except for the module housing 110 and the module cover 170, will be described.

In summary, the haptic actuator assembly 100′ may include the plurality of haptic actuator modules each including only the first electrode 120, the dielectric elastomer 130, the second electrode 140, the third electrode 150, the protruding pin 160, and the power source, an assembly housing 110′ configured to accommodate the plurality of haptic actuator modules, and an assembly cover 170′ configured to open or close the assembly housing 110′.

The assembly housing 110′ may have therein a plurality of accommodation spaces configured to respectively accommodate the plurality of haptic actuator modules.

The accommodation regions formed inside the assembly housing 110′ may also each be formed to surround the lower and outer surfaces of the first electrode 120 included in the haptic actuator module, surround the outer surface of the dielectric elastomer 130, and surround the outer surface of the second electrode 140.

Meanwhile, the protruding pin 160 of the haptic actuator module accommodated in the accommodation region may adjoin lower and upper surfaces of the assembly cover 170′.

That is, the assembly cover 170′ is disposed to cover an opened upper side of the assembly housing 110′, a lower surface of the assembly cover 170′ is disposed to adjoin the protruding pins 160 of the plurality of haptic actuator modules accommodated in the plurality of accommodation regions.

The controller may control the power sources of the plurality of haptic actuator modules to apply voltages or apply no voltage between the first electrodes 120 and the second electrodes 140 of the plurality of haptic actuator modules.

For example, the controller may control the power source of the corresponding haptic actuator module so that a voltage is applied between the first electrode 120 and the second electrode 140 of any one haptic actuator module among the plurality of haptic actuator modules.

Therefore, in the assembly cover 170′, an upper portion of the haptic actuator module having the first electrode 120 and the second electrode 140 between which a voltage is applied, i.e., an upper of the protruding pin 160 of the haptic actuator module having the first electrode 120 and the second electrode 140 between which a voltage is applied may protrude upward as the protruding pin 160 is raised.

Therefore, the controller may control the power sources of the plurality of haptic actuator modules so that the assembly cover 170′ forms protruding patterns having various shapes.

Therefore, the haptic actuator assembly 100′ may provide the user with the pin stimulation that is a sensation in which only a predetermined region (the upper portions of some of the haptic actuator modules) vibrates, and the upper surface of the assembly cover 170′ may provide bumpy resistance.

To this end, the assembly cover 170′ may be made of a flexible material that allows transformable shapes.

Meanwhile, the third electrode 150 of the corresponding haptic actuator module may transmit the electric field, which is generated by the voltage applied between the first electrode 120 and the second electrode 140, to an upper region of the assembly cover 170′, the upper region below which the protruding pin 160 is positioned.

Specifically, when a voltage is applied between the first electrode 120 and the second electrode 140, an electric field is generated even between the protruding pin 160 and the third electrode 150, and the electric field generated between the protruding pin 160 and the third electrode 150 may apply the electrostatic attraction to the user's body (e.g., the finger) that approaches the upper region in which the protruding pin 160 is positioned.

Therefore, when the user's body (e.g., the finger) approaches the assembly cover 170′ in the state in which a voltage is applied between the first electrode 120 and the second electrode 140, the electrostatic attraction may be applied to the user's body to provide the user with a pulling sensation.

Actually, when the user's body (e.g., the finger) approaches the assembly cover 170′ in the state in which the voltage is applied between the first electrode 120 and the second electrode 140, the skin of the user's body (e.g., the finger) may be stretched by being pulled by the electrostatic attraction.

While the present invention has been described above with reference to the exemplary embodiments, it may be understood by those skilled in the art that the present invention may be variously modified and changed without departing from the spirit and scope of the present invention disclosed in the claims.

What is claimed is:

1. A haptic actuator module using electrostatic attraction and pin stimulation, the haptic actuator module comprising:
a dielectric elastomer;
a first electrode disposed to adjoin a lower surface region that is a lower surface of the dielectric elastomer;
a second electrode disposed to adjoin a first upper surface region that is a partial region of an upper surface of the dielectric elastomer; and
a module housing having therein an accommodation region configured to accommodate the dielectric elastomer, the first electrode, and the second electrode, the module housing being configured such that an outer surface region, which is an outer surface of the dielectric elastomer, adjoins an inner surface of the accommodation region.

2. The haptic actuator module of claim 1, further comprising:
a third electrode disposed to adjoin a third upper surface region that is a partial region of a second upper surface region that is an upper surface of the dielectric elastomer that does not adjoin the second electrode; and
a protruding pin having a predetermined thickness and disposed above the third electrode.

3. The haptic actuator module of claim 2, wherein the module housing has a module cover configured to open or close the accommodation region, and an upper surface of the protruding pin adjoins a lower surface of the module cover.

4. The haptic actuator module of claim 3, further comprising:
a power source configured to supply a voltage between the first electrode and the second electrode,
wherein a first elastomer region of the dielectric elastomer, which is disposed below the first upper surface region and between the first electrode and the second electrode, is compressed and decreased in thickness by electrostatic attraction when a voltage is applied between the first electrode and the second electrode.

5. The haptic actuator module of claim 4, wherein a second elastomer region of the dielectric elastomer, which is disposed below the second upper surface region and is the remaining region other than the first elastomer region, increases in thickness while corresponding to the decrease in thickness of the first elastomer region when the voltage is applied between the first electrode and the second

6. The haptic actuator module of claim 5, wherein the third electrode and the protruding pin are raised by the increase in thickness of the second elastomer region when the voltage is applied between the first electrode and the second electrode.

7. The haptic actuator module of claim 5, wherein the module cover protrudes upward as the third electrode and the protruding pin are raised by the increase in thickness of the second elastomer region when the voltage is applied between the first electrode and the second electrode.

8. A haptic actuator assembly using electrostatic attraction and pin stimulation, the haptic actuator assembly comprising:
a plurality of haptic actuator modules using electrostatic attraction and pin stimulation according to claim 1; and
an assembly controller configured to provide haptics by applying voltages between first and second electrodes of one or more haptic actuator modules using electrostatic attraction and pin stimulation among the plurality of haptic actuator modules using electrostatic attraction and pin stimulation,
wherein the plurality of haptic actuator modules using electrostatic attraction and pin stimulation are disposed adjacent to one another.
